(19) United States
(12) Patent Application Publication
(10) Pub. No.: US 2026/0122775 A1
(43) Pub. Date: Apr. 30, 2026

(54) ELECTRONIC DEVICE INCLUDING HEAT DISSIPATION MATERIAL

(71) Applicant: SAMSUNG ELECTRONICS CO., LTD., Suwon-si (KR)

(72) Inventors: Jaebum LEE, Suwon-si (KR); Moonki YEO, Suwon-si (KR); Dohyeon LEE, Suwon-si (KR); Junho LEE, Suwon-si (KR); Seungbum CHOI, Suwon-si (KR)

(21) Appl. No.: 19/375,920

(22) Filed: Oct. 31, 2025

Related U.S. Application Data
(63) Continuation of application No. PCT/KR2025/017692, filed on Oct. 31, 2025.

(30) Foreign Application Priority Data
Oct. 31, 2024 (KR) 10-2024-0152099
Dec. 11, 2024 (KR) 10-2024-0183980

(51) Int. Cl. H05K 1/02; H05K 1/14

(52) U.S. Cl. CPC H05K 1/0272; H05K 1/0209; H05K 1/144; H05K 2201/10015; H05K 2201/10378

(57) ABSTRACT

An electronic device according to an embodiment of the disclosure may include: a hole connected to the inside of a shield can so as to allow a heat dissipation material injected into a circuit board assembly to flow into the shield can. An electronic device according to an embodiment of the disclosure may include at least one guide element disposed around a hole through which a heat dissipation material is injected so as to allow the heat dissipation material to be easily introduced into the shield can.

### CROSS-REFERENCE TO RELATED APPLICATIONS

This application is a continuation of International Application No. PCT/KR2025/017692 designating the United States, filed on Oct. 31, 2025, in the Korean Intellectual Property Receiving Office and claiming priority to Korean Patent Application Nos. 10-2024-0152099, filed on Oct. 31, 2024, and 10-2024-0183980, filed on Dec. 11, 2024, in the Korean Intellectual Property Office, the disclosures of each of which are incorporated by reference herein in their entireties.

### BACKGROUND

### Field

The disclosure relates to an electronic device and, for example, to an electronic device including a heat dissipation material.

### Description of Related Art

The term “electronic device” may refer to a device that performs a specific function according to an installed program, such as a home appliance, an electronic scheduler, a portable multimedia player, a mobile communication terminal, a tablet PC, an image and sound device, a desktop or laptop PC, or a vehicle navigation system. For example, these electronic devices may output stored information as sound or images.

As the degree of integration of electronic devices increases and ultra-high-speed and high-capacity wireless communication become more widespread, a single electronic device, such as a mobile communication terminal, may be now equipped with various functions. For example, not only communication functions but also entertainment functions such as gaming, multimedia functions such as music and video playback, communication and security functions such as mobile banking, as well as schedule management and electronic wallet functions, are being integrated into a single electronic device. These electronic devices are being miniaturized to be conveniently carried by users.

### SUMMARY

According to an embodiment of the disclosure, an electronic device may include: a housing at least partially forming an exterior of the electronic device, and a circuit board assembly disposed inside the housing; wherein circuit board assembly may include: a first printed circuit board including a first surface and a second surface opposite to the first surface, a second printed circuit board spaced apart from the first printed circuit board and including a third surface facing the first surface, an interposer disposed between the first surface and the third surface and electrically connecting the first printed circuit board and the second printed circuit board, a first hole disposed in the first printed circuit board and/or the second printed circuit board and configured to connect the outside of the circuit board assembly and a first space defined by the first printed circuit board, the second printed circuit board, and the interposer, a shield can disposed on the second surface of the first printed circuit board, a second hole disposed in the first printed circuit board and connecting the first space and a second space defined by the shield can and the first printed circuit board, a gel-type heat dissipation material disposed in the first space and the second space, and at least one guide element disposed on the first surface and/or the third surface and around the second hole.

According to an embodiment of the disclosure, the at least one guide element disposed on at least one of the first surface of the first printed circuit board and/or the third surface of the second printed circuit board and at least partially surrounding the second hole at a position spaced apart from an area between the first hole and the second hole.

According to an embodiment of the disclosure, the at least one guide element may be configured to guide the heat dissipation material injected into the first space through the first hole to the second hole so as to allow the heat dissipation material to flow into the second space.

According to an embodiment of the disclosure, an electronic device may include: a housing at least partially forming an exterior of the electronic device, and a circuit board assembly disposed inside the housing, wherein the circuit board assembly may include: a first printed circuit board including a first surface and a second surface opposite to the first surface, a second printed circuit board spaced apart from the first printed circuit board and including a third surface facing the first surface, an interposer disposed between the first surface and the third surface and electrically connecting the first printed circuit board and the second printed circuit board, a first hole disposed in the first printed circuit board and/or the second printed circuit board and connecting the outside of the circuit board assembly and a first space defined by the first printed circuit board, the second printed circuit board, and the interposer, a shield can disposed on the second surface of the first printed circuit board, a second hole disposed in the first printed circuit board and connecting the first space and a second space defined by the shield can and the first printed circuit board, and a gel-type heat dissipation material configured to flow into the first space through the first hole and into the second space through the second hole.

According to an embodiment of the disclosure, an electronic device may include a housing forming an exterior of the electronic device, a circuit board assembly disposed inside the housing, wherein the circuit board assembly comprises a first printed circuit board comprising a first surface and a second surface opposite to the first surface, a second printed circuit board comprising a third surface facing the first surface, an interposer disposed between the first printed circuit board and the second printed circuit board to define a first space with the first printed circuit board and the second printed circuit board, wherein the interposer is configured to electrically connect the first printed circuit board and the second printed circuit board, a shield can disposed at the second surface of the first printed circuit board to define a second space with the first printed circuit board, an introducing hole formed in the first printed circuit board, a heat dissipation material disposed in the first space and the second space, and at least one guide element disposed on the first surface and/or the third surface and around the introducing hole, wherein the at least one guide element is configured to guide a portion of the heat dissipation material in a gel state injected into the first space to flow into the second space through the introducing hole.

### BRIEF DESCRIPTION OF THE DRAWINGS

The above and other aspects, features and advantages of certain embodiments of the present disclosure will be more apparent from the following detailed description, taken in conjunction with the accompanying drawings.

FIG. 1 is a block diagram illustrating an electronic device in a network environment according to various embodiments;

FIG. 2 is a front perspective view of an electronic device according to an embodiment of the disclosure.

FIG. 3 is a perspective view of the electronic device according to an embodiment of the disclosure, illustrating the rear surface of the electronic device.

FIG. 4 is an exploded perspective view of a circuit board assembly according to an embodiment of the disclosure.

FIG. 5 illustrates a view of the circuit board assembly according to an embodiment of the disclosure as viewed from above a first printed circuit board.

FIG. 6 illustrates a view of the circuit board assembly according to an embodiment of the disclosure, into which a heat dissipation material is not injected, as viewed from above the first printed circuit board.

FIG. 7 is a cross-sectional view of the circuit board assembly according to an embodiment of the disclosure, taken along line A-A′ of FIG. 5.

FIG. 8 is a cross-sectional view taken along line B-B′ of FIG. 6, illustrating a state in which the heat dissipation material is injected.

FIG. 9 illustrates a view of the first printed circuit board as viewed from above a first surface, according to an embodiment of the disclosure.

FIG. 10 is an enlarged view illustrating a partial area of the first surface according to an embodiment of the disclosure shown in FIG. 9.

FIG. 11 is a view illustrating a circuit board assembly according to an embodiment of the disclosure as viewed from above a first printed circuit board.

FIG. 12 is a cross-sectional view of a circuit board assembly according to an embodiment of the disclosure, taken along line A-A′ of FIG. 5.

FIG. 13 is a cross-sectional view of a circuit board assembly according to an embodiment of the disclosure, taken along line A-A′ of FIG. 5.

### DETAILED DESCRIPTION

The following description made with reference to the accompanying drawings may provide an understanding of various example embodiments of the disclosure including the claims and equivalents thereof. An exemplary embodiment set forth in the following description includes various particular details to help the understanding, but is considered one of various exemplary embodiments. Therefore, it will be apparent to those skilled in the art that various changes and modifications may be made to various implementations described herein without departing from the scope and technical idea of the disclosure. In addition, descriptions of well-known functions and configurations may be omitted for clarity and brevity.

The terms and words used in the following description and claims are not limited to bibliographical meanings, but may be used to clearly and consistently describe the various embodiments set forth herein. Therefore, it will be apparent to those skilled in the art that the following description of various implementations of the disclosure is provided for the purpose of explanation, rather than for the purpose of limiting the disclosure.

It should be appreciated that a singular form such as “a,” “an,” or “the” also includes the meaning as a plural form, unless the context clearly indicates otherwise. Therefore, for example, “a component surface” may refer to one or more of component surfaces.

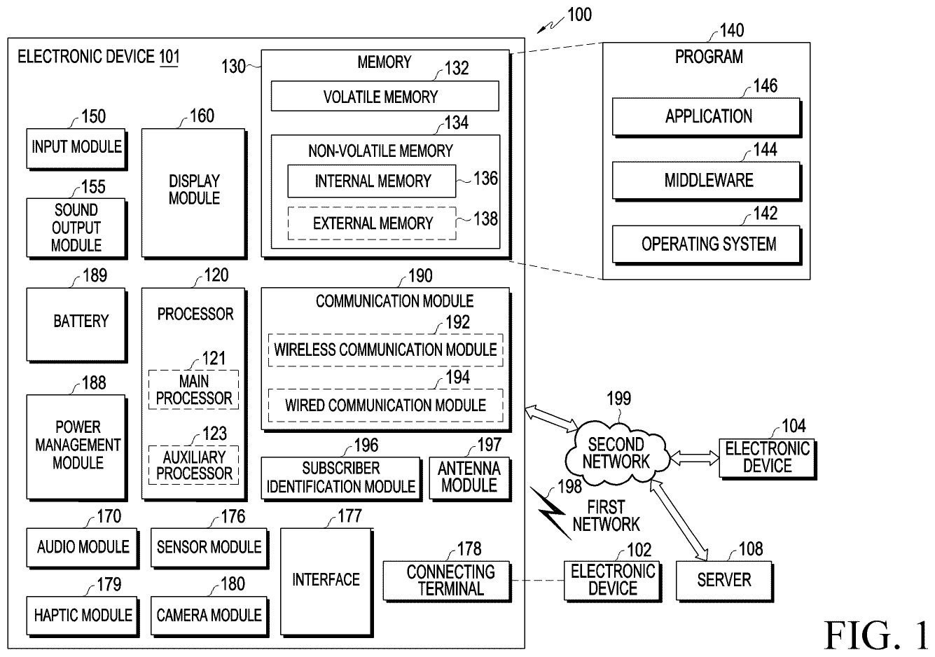

FIG. 1 is a block diagram illustrating an electronic device 101 in a network environment 100 according to various embodiments.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

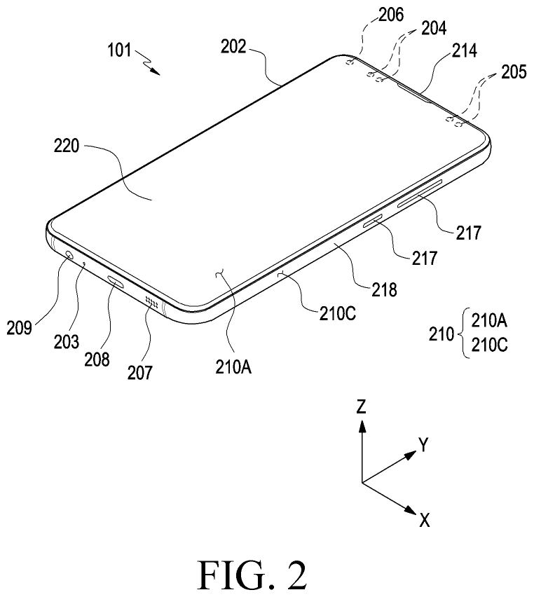

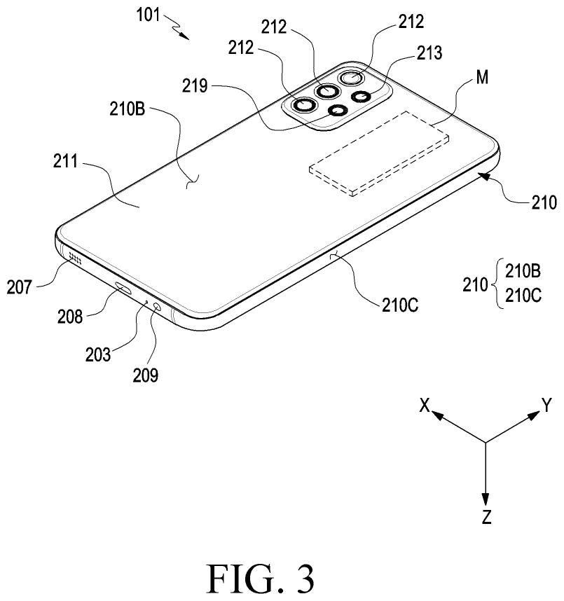

FIG. 2 is a perspective view of the electronic device 101 according to an embodiment of the disclosure, illustrating the front surface 210A of the electronic device 101. FIG. 3 is a perspective view of the electronic device 101 according to an embodiment of the disclosure, illustrating the rear surface 210B of the electronic device 101.

Referring to FIGS. 2 and 3, according to an embodiment of the disclosure, the electronic device 101 may include a housing 210 forming at least a portion of the exterior of the electronic device 101. The housing 210 may include a first surface (or front surface) 210A, a second surface (or rear surface) 210B, and a third surface (or side surface) 210C surrounding a space between the first surface 210A and the second surface 210B.

According to an embodiment of the disclosure, at least a portion of the first surface 210A may be made of a substantially transparent front surface plate 202 (e.g., a glass plate or a polymer plate including various coating layers). The second surface 210B may be made of a substantially opaque rear surface plate 211. The rear surface plate 211 may be made of, for example, coated or colored glass, ceramic, polymer, metal (e.g., aluminum, stainless steel (STS), or magnesium), or a combination of two or more of these materials. The side surface 210C may be defined by the side surface structure (or a “side surface bezel structure”) 218 coupled to the front surface plate 202 and the rear surface plate 211 and including metal and/or polymer. In an embodiment, the rear surface plate 211 and the side surface structure 218 may be integrated with each other and may include the same material (e.g., a metal material such as aluminum).

According to an embodiment of the disclosure, the electronic device 101 may include at least one of a display 220, audio modules 203, 207, and 214, sensor modules 204 and 219, camera modules 205, 212, and 213, key input devices 217, light-emitting elements 206, and connector holes 208 and 209. In an embodiment, the electronic device 101 may omit at least one of the components (e.g., the key input devices 217 or the light-emitting element 206) or may additionally include other components.

According to an embodiment of the disclosure, the display 220 may be visually exposed through a substantial portion of, for example, the front surface plate 202. In an embodiment, at least a portion of the display 220 may be visible through the front surface plate 202 forming the first surface 210A or through a portion of the side surface 210C. In an embodiment, the edge of the display 220 may be formed to be substantially the same as the shape of the periphery of the front surface plate 202 adjacent thereto.

In an embodiment of the disclosure (not illustrated), recesses or openings may be provided in a portion of the screen display area of the display 220, and one or more of the audio module 214, the sensor modules 204, the camera modules 205, and the light-emitting elements 206, which are aligned with the recesses or the openings, may be included. In an embodiment of the disclosure (not illustrated), the rear surface of the screen display area of the display 220 may include at least one of the audio module 214, the sensor modules 204, the camera modules 205, a fingerprint sensor (not illustrated), and the light-emitting elements 206. In an embodiment of the disclosure (not illustrated), the display 220 may be coupled to or disposed adjacent to a touch-sensitive circuit, a pressure sensor capable of measuring a touch intensity (pressure), and/or a digitizer configured to detect an electromagnetic field-type stylus pen.

According to an embodiment of the disclosure, the audio modules 203, 207, and 214 may include a microphone hole 203 and speaker holes 207 and 214. A microphone configured to acquire external sound may be placed inside the microphone hole 203, and in an embodiment, multiple microphones may be placed to detect the direction of sound. The speaker holes 207 and 214 may include an external speaker hole 207 and a communication receiver hole 214. In an embodiment, the speaker holes 207 and 214 and the microphone hole 203 may be implemented as a single hole, or a speaker (e.g., a piezo speaker) may be included without the speaker holes 207 and 214.

According to an embodiment of the disclosure, the sensor modules 204 and 219 may generate electrical signals or data values corresponding to an internal operating state or an external environmental state of the electronic device 101. The sensor modules 204 and 219 may include, for example, a first sensor module 204 (e.g., a proximity sensor) and/or a second sensor module (not illustrated) (e.g., a fingerprint sensor) disposed on the first surface 210A of the housing 210, and/or a third sensor module 219 and/or a fourth sensor module (e.g., a fingerprint sensor) disposed on the second surface 210B of the housing 210. The fingerprint sensor may be disposed not only on the first surface 210A (e.g., the display 220) of the housing 210, but also on the second surface 210B or the side surface 210C of the housing 210. The electronic device 101 may further include at least one of, for example, a gesture sensor, a gyro sensor, an atmospheric pressure sensor, a magnetic sensor, an acceleration sensor, a grip sensor, a color sensor, an infrared (IR) sensor, a biometric sensor, a temperature sensor, a humidity sensor, or an illuminance sensor.

According to an embodiment of the disclosure, the camera modules 205, 212, and 213 may include a first camera device 205 disposed on the first surface 210A of the electronic device 101, and a second camera device 212 and/or a flash 213 disposed on the second surface 210B. The camera devices 205 and 212 may include one or more lenses, an image sensor, and/or an image signal processor. The flash 213 may include, for example, a light-emitting diode or a xenon lamp. In an embodiment, two or more lenses (e.g., an infrared camera lens, a wide-angle lens, and a telephoto lens) and image sensors may be disposed on one surface of the electronic device 101. In an embodiment, the flash 213 may emit infrared rays, and the infrared light emitted by the flash 213 and reflected by a subject may be received through the third sensor module 219. The electronic device 101 or the processor of the electronic device 101 may detect depth information of the subject based on a time point when infrared rays are received from the third sensor module 219.

According to an embodiment of the disclosure, the key input devices 217 may be disposed on the side surface 210C of the housing 210. In an embodiment, the electronic device 101 may not include some or all of the above-mentioned key input devices 217, and key input devices 217, which are not included, may be implemented in another form, such as soft keys, on the display 220. In an embodiment, the key input devices may include a sensor module disposed on the second surface 210B of the housing 210.

According to an embodiment of the disclosure, the light-emitting element 206 may be disposed on, for example, the first surface 210A of the housing 210. The light-emitting element 206 may provide, for example, the state information of the electronic device 101 in an optical form. In an embodiment, the light-emitting element 206 may provide, for example, a light source that operates in conjunction with the camera module 205. The light-emitting element 206 may include, for example, an LED, an IR LED, and a xenon lamp.

The connector holes 208 and 209 may include a first connector hole 208 capable of accommodating a connector (e.g., a USB connector) configured to transmit/receive power and/or data to/from an external electronic device, and/or a second connector hole (e.g., an earphone jack) 209 capable of accommodating a connector configured to transmit/receive an audio signal to/from an external electronic device.

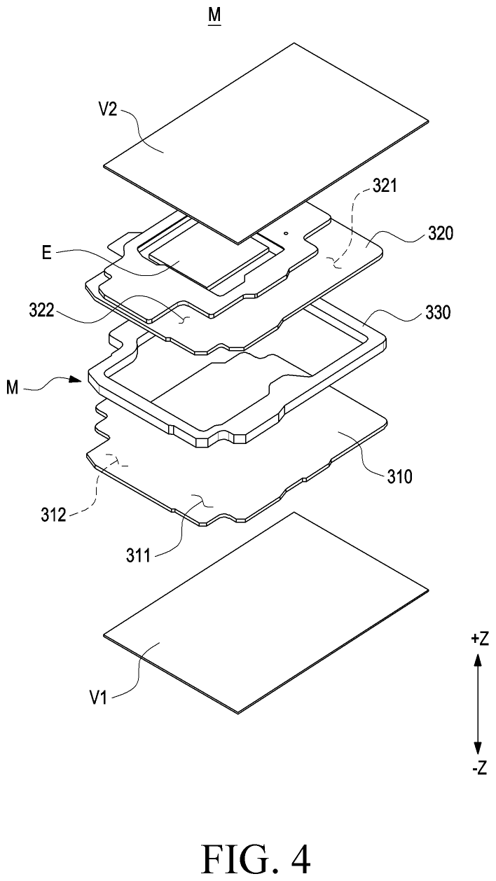

According to an embodiment of the disclosure, the electronic device 101 may include a circuit board assembly M disposed inside the housing 210. The circuit board assembly M may be positioned between the display 220 and the rear surface plate 211. The circuit board assembly M according to an embodiment of the disclosure will be described in detail below with reference to FIGS. 4 to 13.

FIG. 4 is an exploded perspective view of the circuit board assembly M according to an embodiment of the disclosure.

Referring to FIG. 4, the circuit board assembly M according to an embodiment of the disclosure may include a first printed circuit board 310 and a second printed circuit board 320. A plurality of electronic components of the electronic device 101 (e.g., the processor 120, the memory 130, and/or the communication module 190 of FIG. 1) may be disposed at the circuit board assembly M. The circuit board assembly M may include an interposer 330 configured to electrically connect the first printed circuit board 310 and the second printed circuit board 320.

According to an embodiment of the disclosure, the first printed circuit board 310 may include a first surface 311 and a second surface 312 opposite to the first surface 311. Electronic components or electronic elements of the electronic device 101 may be disposed on the first surface 311 and/or the second surface 312. The second printed circuit board 320 may be spaced apart from the first printed circuit board 310. The second printed circuit board 320 may be positioned to face the first printed circuit board. The second printed circuit board 320 may include a third surface 321 facing the first surface 311 of the first printed circuit board 310. The second printed circuit board 320 may include a fourth surface 322 opposite to a third surface 321. Electronic components or electronic elements of the electronic device 101 may be disposed on the third surface 321 and/or the fourth surface 322.

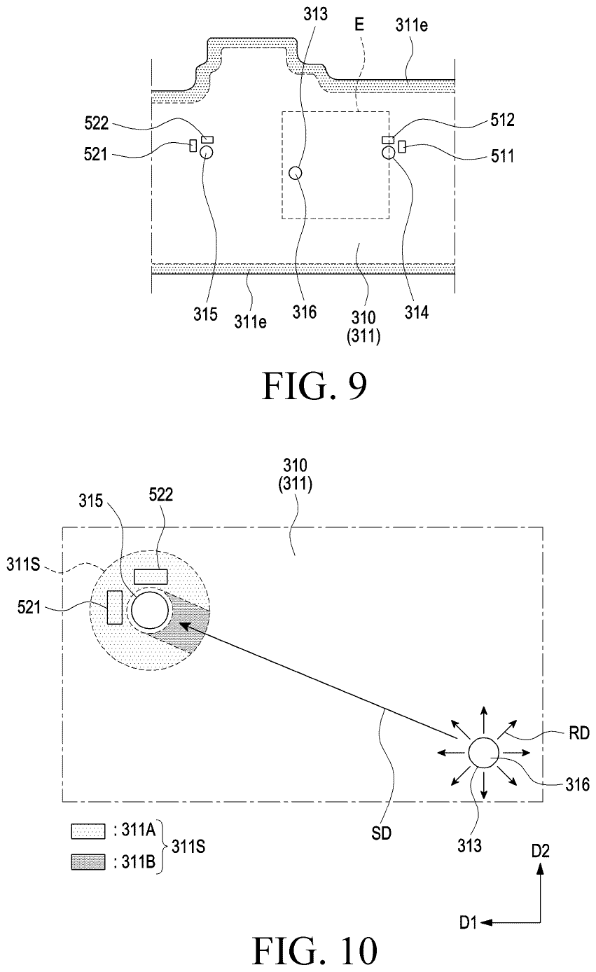

According to an embodiment of the disclosure, the interposer 330 may be disposed between the first printed circuit board 310 and the second printed circuit board 320. The interposer 330 may electrically connect the first printed circuit board 310 and the second printed circuit board 320. The interposer 330 may include a plurality of vias configured to electrically connect the first printed circuit board 310 and the second printed circuit board 320. For example, the interposer 330 may be electrically connected to the first printed circuit board 310 and the second printed circuit board 320 by being soldered to a plurality of vias disposed at an edge 311e (see FIG. 9) of the first printed circuit board 310 and a plurality of vias disposed at an edge of the second printed circuit board 320.

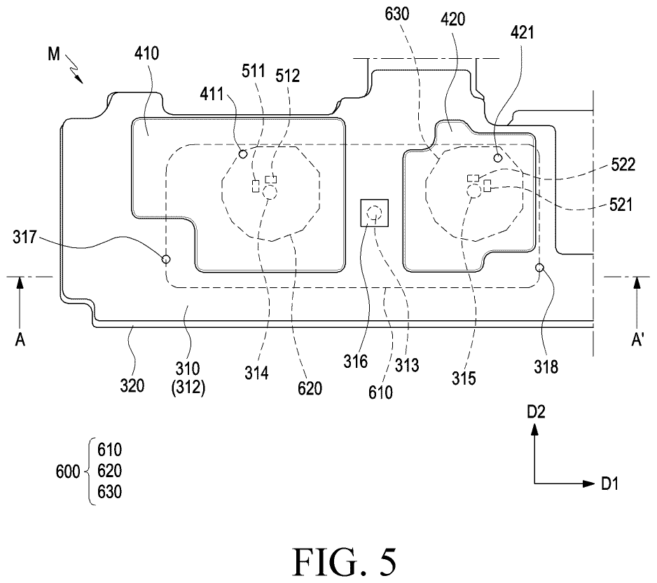

According to an embodiment of the disclosure, the interposer 330 may extend in a loop shape along at least a portion of the edge of the second printed circuit board 320. The interposer 330 extending in the loop shape may provide a space in which electronic components (e.g., the guide elements 511, 512, 521, and 522 of FIG. 5) are disposed between the first printed circuit board 310 and the second printed circuit board 320.

According to an embodiment of the disclosure, the circuit board assembly M may include an electronic component E. The electronic component E may be disposed on the second surface 312 of the first printed circuit board 310 or on the fourth surface 322 of the second printed circuit board 320. FIG. 4 illustrates a case where the electronic component E is mounted on the fourth surface 322 of the second printed circuit board 320 by way of an example. The electronic component E may be disposed so as to at least partially overlap a shield can 410 or 420 when viewed from above the second surface 312 of the first printed circuit board 310 or the fourth surface 322 of the second printed circuit board 320.

According to an embodiment of the disclosure, the electronic component E may be an integrated circuit. For example, the electronic component E may be a processor 120 (see FIG. 1). In another example, the electronic component E may be an integrated circuit package in which the processor 120 (see FIG. 1) and memory 130 are sequentially stacked.

According to an embodiment of the disclosure, the electronic device 101 may include a first thermal diffusion sheet V1 spaced apart from the circuit board assembly M in a direction in which the second surface 312 of the first printed circuit board 310 is oriented and configured to diffuse heat generated from the circuit board assembly M. The first thermal diffusion sheet V1 may be disposed inside the housing 210. The first thermal diffusion sheet V1 may be disposed to face the rear surface plate 211 (see FIG. 3). The first thermal diffusion sheet V1 may have a form extending parallel to the rear surface plate 211 (see FIG. 3).

According to an embodiment of the disclosure, the electronic device 101 may include a second thermal diffusion sheet V2 spaced apart from the circuit board assembly M in a direction in which the fourth surface 322 of the second printed circuit board 320 is oriented and configured to diffuse heat generated from the circuit board assembly M. The circuit board assembly M may be disposed between the first thermal diffusion sheet V1 and the second thermal diffusion sheet V2. The second thermal diffusion sheet V2 may be disposed inside the housing 210. The second thermal diffusion sheet V2 may be disposed under the display 220 (see FIG. 2). The second thermal diffusion sheet V2 may have a form extending parallel to the display 220.

According to an embodiment of the disclosure, the first thermal diffusion sheet V1 and the second thermal diffusion sheet V2 may be referred to as heat dispersion members. Heat generated from the circuit board assembly M may be diffused through the first thermal diffusion sheet V1 and the second thermal diffusion sheet V2. For example, the first thermal diffusion sheet V1 and the second thermal diffusion sheet V2 may include a vapor chamber or a heat pipe.

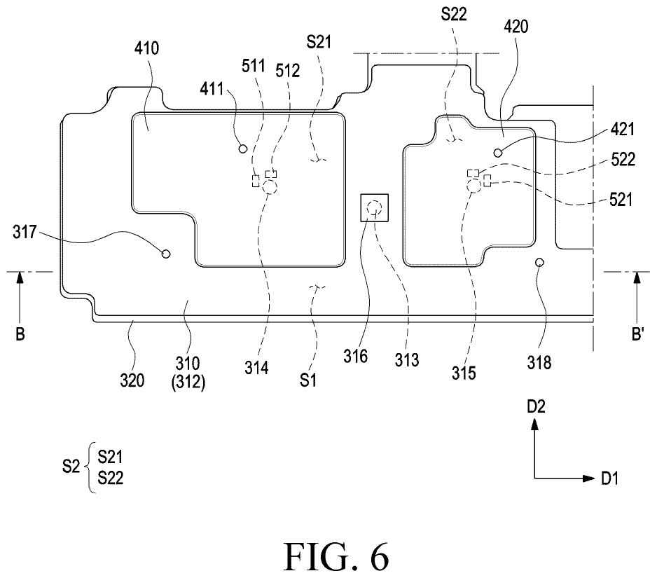

FIG. 5 illustrates a view of the circuit board assembly M according to an embodiment of the disclosure as viewed from above the first printed circuit board 310. FIG. 6 illustrates a view of the circuit board assembly M according to an embodiment of the disclosure as viewed from above the first printed circuit board 310 in a state in which a heat dissipation material 600 is not injected. The coordinate axes illustrated in FIGS. 5 and 6 include a first direction D1 and a second direction D2 orthogonal to each other. For example, the first direction D1 may be parallel to the Y-axis direction illustrated in FIGS. 2 and 3, and the second direction D2 may be parallel to the X-axis direction illustrated in FIGS. 2 and 3.

Referring to FIGS. 5 and 6, the circuit board assembly M according to an embodiment of the disclosure may include a first hole 313 disposed in the first printed circuit board 310 or the second printed circuit board 320. FIGS. 5 and 6 illustrate a case where the first hole 313 is disposed in the first printed circuit board 320 by way of a non-limiting example.

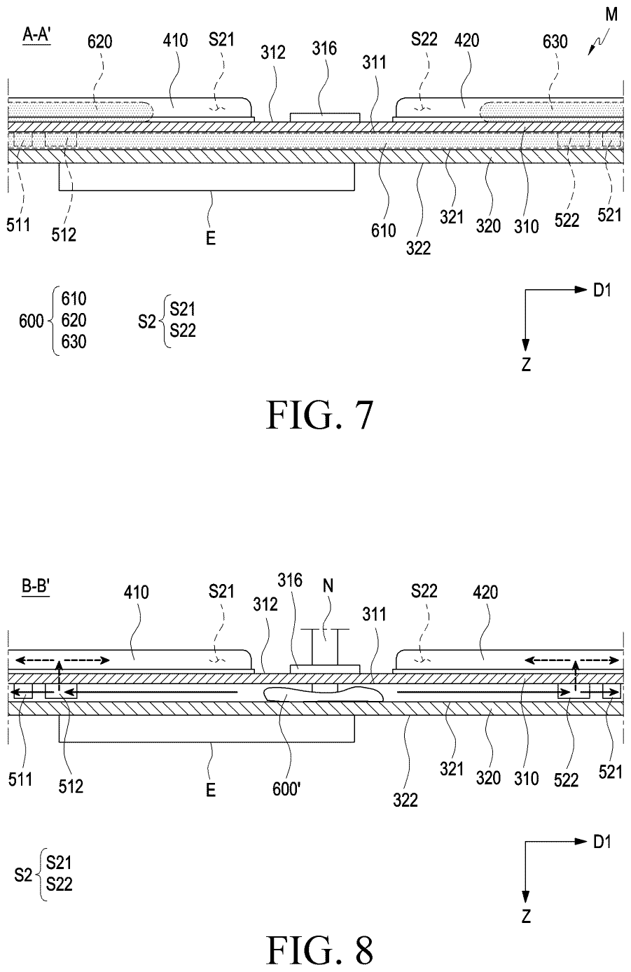

According to an embodiment of the disclosure, the circuit board assembly M may include a cap 316 disposed on the second surface 312 of the first printed circuit board 310 and covering the first hole 313. For example, the cap 316 may be made of a rubber material. The cap 316 may include a slit for insertion of an injector N (see FIG. 8). The cap 316 will be described in detail below with reference to FIGS. 7 and 8.

According to an embodiment of the disclosure, the first hole 313 may penetrate through the first printed circuit board 310. The first hole 313 may connect a first hole 313 that connects the outside of the circuit board assembly M and a first space S1 defined by the first printed circuit board 310, the second printed circuit board 320, and the interposer 330. The outside of the circuit board assembly M and the first space S1 may be spatially connected to each other through the first hole 313. A heat dissipation material 600 may be injected into the first space S1 through the first hole 313. The first hole 313 may be referred to as an injection hole.

According to an embodiment of the disclosure, the circuit board assembly M may include shield cans 410 and 420 disposed on the second surface 312 of the first printed circuit board 310. The shield cans 410 and 420 and the first printed circuit board 310 may define a second space S2. For convenience of description, the shield cans 410 and 420 illustrated in FIGS. 5 and 6 may be referred to as a first shield can 410 and a second shield can 420. A space defined by the first shield can 410 may be referred to as a (2-1)^{th} space S21, and a space defined by the second shield can 420 may be referred to as a (2-2)^{th} space S22.

According to an embodiment of the disclosure, the circuit board assembly M may include second holes 314 and 315 disposed in the first printed circuit board 310 and configured to connect the first space S1 and the second space S2 defined by the shield can 410 and 420 and the first printed circuit board 310. When viewed from above the second surface 312 of the first printed circuit board 310, the second holes 314 and 315 may be covered by the shield cans 410 and 420. The first space S1 and the second space S2 may be spatially connected through the second holes 314 and 315. The heat dissipation material 600 may flow from the first space S1 into the second space S2 through the second holes 314 and 315. The second holes 314 and 315 may be referred to as introducing holes. For convenience of explanation, the second holes 314 and 315 may be referred to as a (2-1)^{th} hole 314 and a (2-2)^{th} hole 315, or as a first introducing hole 314 and a second introducing hole 315.

According to an embodiment of the disclosure, the circuit board assembly M may include a heat dissipation material 600 disposed in the first space S1 and the second space S2. The heat dissipation material 600 may be understood as a gel-type material including various components. The term “gel-type heat dissipation material” may be understood as a material that has a predetermined (e.g., specified) range of viscosity that is capable of being injected through an injector N (see, e.g., FIG. 8) and does not flow with a large displacement inside the circuit board assembly M (e.g., the first space S1 and the second space S2). For example, the heat dissipation material 600 may include heat dissipation particles (e.g., Al₂O₃ and/or AlN), additives (such as curing agents and catalysts), a silicone resin, and a silicone oil, but is not limited thereto.

According to an embodiment of the disclosure, the heat dissipation material 600 may include a first portion 610 disposed in the first space S1 and second portions 620 and 630 disposed in the second space S2. A portion of the heat dissipation material 600 that is injected into the first space S1 through the first hole 313 and positioned in the first space S1 may be referred to as a first portion 610. A portion of the heat dissipation material 600 that is introduced into the second space S2 through the second holes 314 and 315 and is positioned in the second space S2 may be referred to as second portions 620 and 630. A portion of the heat dissipation material 600 positioned in the (2-1)^{th} space S21 may be referred to as a (2-1)^{th} portion 620. A portion of the heat dissipation material 600 positioned in the (2-2)^{th} space S22 may be referred to as a (2-2)^{th} portion 630.

According to an embodiment of the disclosure, the first shield can 410 may include a first shield can hole 411. Through the first shield can hole 411, the (2-1)^{th} portion 620 of the heat dissipation material 600 positioned in the (2-1)^{th} space S21 may be visually exposed. The second shield can 420 may include a second shield can hole 421. Through the second shield can hole 421, the (2-2)^{th} portion 630 of the heat dissipation material 600 positioned in the (2-2)^{th} space S22 may be visually exposed.

Referring to FIGS. 4 to 6, according to an embodiment of the disclosure, the electronic component E may be positioned between the second thermal diffusion sheet V2 and the first portion 610 of the heat dissipation material 600. The second portions 620 and 630 of the heat dissipation material 600 may be positioned between the first thermal diffusion sheet V1 and the first portion 610 of the heat dissipation material 600. Heat generated from the circuit board assembly M and/or the electronic component E may be dissipated to the outside of the circuit board assembly M through the first portion 610 and/or the second portions 620 and 630 of the heat dissipation material 600. The heat released to the outside of the circuit board assembly M may be diffused through the first thermal diffusion sheet V1 and/or the second thermal diffusion sheet V2. The heat diffused through the first thermal diffusion sheet V1 and/or the second thermal diffusion sheet V2 may be dissipated to the outside of the electronic device 101 through a surface (e.g., the first surface 210A of FIG. 2 and/or the second surface 210B of FIG. 3) of the electronic device 101.

According to an embodiment of the disclosure, the circuit board assembly M may include at least one guide element 511, 512, 521, or 522 disposed on at least one of the first surface 311 of the first printed circuit board 310 or the third surface 321 of the second printed circuit board 320. For example, the guide element 51, 512, 521, or 522 may be referred as an electrical element (e.g., capacitor) which is electrically connected to the first printed circuit board 310 or to the second printed circuit board 320.

According to an embodiment of the disclosure, the at least one guide element 511, 512, 521, or 522 may be configured to guide the heat dissipation material 600, injected into the first space S1 through the first hole 313, to the second hole 314 or 315 so as to allow the heat dissipation material 600 to flow into the second space S2. For example, FIGS. 5 to 10 illustrate a case where the guide element 511, 512, 521, or 522 is disposed on the first surface 311 of the first printed circuit board 310.

According to an embodiment of the disclosure, the guide element 511, 512, 521, or 522 may protrude from at least one of the first surface 311 of the first printed circuit board 310 and a third surface 321 of the second printed circuit board 320. The height of the guide element 511, 512, 521, or 522 protruding from at least one of the first surface 311 of the first printed circuit board 310 or the third surface 321 of the second printed circuit board 320 may be greater than half of a distance between the first surface 311 of the first printed circuit board 310 and the third surface 321 of the second printed circuit board 320.

According to an embodiment of the disclosure, the guide element 511, 512, 521, or 522 may be components of a part of an electric circuit for performing a function of the electronic device 101, or components disposed on the first printed circuit board 310 or the second printed circuit board 320 independently of the function of the electronic device 101. For example, the guide element 511, 512, 521, or 522 may include a decoupling capacitor.

According to an embodiment of the disclosure, a plurality of guide elements 511, 512, 521, and 522 may be provided. For convenience of description, the guide elements 511 and 512 arranged around the (2-1)^{th} hole 314 may be referred to as a (1-1)^{th} guide element 511 and a (1-2)^{th} guide element 512. For convenience of description, the guide elements 521 and 522 arranged around the (2-2)^{th} hole 315 may be referred to as a (2-1)^{th} guide element 521 and a (2-2)^{th} guide element 522. The (1-1)^{th} guide element 511 and the (2-1)^{th} guide element 521 may be collectively referred to as first guide elements 511 and 521, and the (1-2)^{th} guide element 512 and the (2-2)^{th} guide element 522 may be collectively referred to as second guide elements 512 and 522.

According to an embodiment of the disclosure, the (1-1)^{th} guide element 511 and the (1-2)^{th} guide element 512 may be disposed around the (2-1)^{th} hole 314. The (1-1)^{th} guide element 511 and the (1-2)^{th} guide element 512 may at least partially surround the (2-1)^{th} hole 314. The (1-1)^{th} guide element 511 and the (1-2)^{th} guide element 512 may be arranged along a periphery of the (2-1)^{th} hole 314. The (1-1)^{th} guide element 511 and the (1-2)^{th} guide element 512 may be configured to guide the heat dissipation material 600 to the (2-1)^{th} hole 314 so that the heat dissipation material 600 flows into the (2-1)^{th} space S21. The (2-1)^{th} hole 314 may be positioned between the first hole 313 and the (1-1)^{th} guide element 511 and the (1-2)^{th} guide element 512.

According to an embodiment of the disclosure, the (2-1)^{th} guide element 521 and the (2-2)^{th} guide element 522 may be disposed around the (2-2)^{th} hole 315. The (2-1)^{th} guide element 521 and the (2-2)^{th} guide element 522 may at least partially surround the (2-2)^{th} hole 315. The (2-1)^{th} guide element 521 and the (2-2)^{th} guide element 522 may be arranged along a periphery of the (2-2)^{th} hole 315. The (2-1)^{th} guide element 521 and the (2-2)^{th} guide element 522 may be configured to guide the heat dissipation material 600 to the (2-2)^{th} hole 315 so that the heat dissipation material 600 flows into the (2-2)^{th} space S22. The (2-2)^{th} hole 315 may be positioned between the first hole 313 and the (2-1)^{th} guide element 521 and the (2-2)^{th} guide element 522.

According to an embodiment of the disclosure, the circuit board assembly M may include third holes 317 and 318 disposed in the first printed circuit board 310. A portion 610 of the heat dissipation material 600 disposed in the first space S1 may be visually exposed to the outside of the circuit board assembly M through the third holes 317 and 318. The third holes 317 and 318 may be spaced farther from the first hole 313 than the second holes 314 and 315. The third holes 317 and 318 may be referred to as inspection holes. For convenience of description, the third holes 317 and 318 may be referred to as a (3-1)^{th} hole 317 and a (3-2)^{th} hole 318.

According to an embodiment of the disclosure, the (3-1)^{th} hole 317 may be spaced apart from the first hole 313 in a direction intersecting a direction in which the (2-1)^{th} hole 314 is spaced apart from the first hole 313. The (3-1)^{th} hole 317 may be spaced farther from the first hole 313 than the (2-1)^{th} hole 314. The first portion 610 of the heat dissipation material 600 may be visually exposed through the (3-1)^{th} hole 317. The (3-1)^{th} hole 317 may be referred to as a first inspection hole 317.

According to an embodiment of the disclosure, the (3-2)^{th} hole 318 may be spaced apart from the first hole 313 in a direction intersecting a direction in which the (2-2)^{th} hole 315 is spaced apart from the first hole 313. The (3-2)^{th} hole 318 may be spaced farther from the first hole 313 than the (2-2)^{th} hole 315. The first portion 610 of the heat dissipation material 600 may be visually exposed through the (3-2)^{th} hole 318. The (3-2)^{th} hole 318 may be referred to as a second inspection hole 318.

According to an embodiment of the disclosure, the first shield can hole 411, the second shield can hole 421, the (3-1)^{th} hole 317, and/or the (3-2)^{th} hole 318 may be covered by transparent films. The first portion 610 of the heat dissipation material 600 may be visually exposed through the transparent films covering the (3-1)^{th} hole 317 and the (3-2)^{th} hole 318. The (2-1)^{th} portion 620 of the heat dissipation material 600 may be visually exposed through the transparent film covering the first shield can hole 411. The (2-2)^{th} portion 630 of the heat dissipation material 600 may be visually exposed through the transparent film covering the second shield can hole 421.

According to an embodiment of the disclosure, the heat dissipation material 600 injected through the first hole 313 may flow into a plurality of spaces (e.g., the first space S1 and the second space S2) through the second holes 314 and 315 connecting the plurality of spaces (e.g., the first space S1 and the second space S2) inside the circuit board assembly M. According to an embodiment of the disclosure, because the electronic device 101 includes the second holes 314 and 315, the heat dissipation material 600 may be injected into the plurality of spaces (e.g., the first space S1 and the second space S2) of the circuit board assembly M through a single process of injecting the heat dissipation material 600 through the first hole 313.

According to an embodiment of the disclosure, because the heat dissipation material 600 injected through the first hole 313 is guided by the guide elements 511, 512, 521, and 522 to easily flow into the second holes 314 and 315, the heat dissipation material 600 may be uniformly introduced into the plurality of spaces (e.g., the first space S1 and the second space S2) of the circuit board assembly M.

FIG. 7 is a cross-sectional view of the circuit board assembly M according to an embodiment of the disclosure, taken along line A-A′ of FIG. 5. FIG. 8 is a cross-sectional view taken along line B-B′ of FIG. 6, illustrating a state in which a heat dissipation material 600′ is injected. It should be understood that solid arrows and dashed arrows illustrated in FIG. 8 represent flows of the heat dissipation material 600′ injected into the circuit board assembly M.

Referring to FIGS. 7 and 8, according to an embodiment of the disclosure, the heat dissipation material 600 of the circuit board assembly M may be injected into the first space S1 by an injector N inserted into the first hole 313. The injector N may be inserted into the first space S1 through the cap 316. The heat dissipation material 600′ injected into the first space S1 may spread from the first hole 313. For example, the heat dissipation material 600′ injected through the first hole 313 may spread in a radial direction RD (see FIG. 10) with respect to the first hole 313.

According to an embodiment of the disclosure, the heat dissipation material 600′ injected into the first space S1 may flow into the second space S2 through the second holes 314 and 315. The heat dissipation material 600′ spreading in the first space S1 may be guided to the second holes 314 and 315 by the guide elements 511, 512, 521, and 522 to flow into the second space S2 through the second holes 314 and 315. The heat dissipation material 600 introduced into the second space S2 may spread from the second holes 314 and 315. For example, the injected heat dissipation material 600 may spread in a radial direction (e.g., the radial direction RD of FIG. 10) with respect to the second holes 314 and 315.

FIG. 9 illustrates a view of the first printed circuit board 310 as viewed from above the first surface 311, according to an embodiment of the disclosure. FIG. 10 is an enlarged view illustrating a partial area of the first surface 311 according to an embodiment of the disclosure shown in FIG. 9.

The description regarding the first surface 311 of the first printed circuit board 310 with reference to FIGS. 9 and 10 may be substantially equally applied to the third surface 321 of the second printed circuit board 320 to the extent that they are not contradictory to each other. The description regarding the (2-2)^{th} hole 315 made with reference to FIG. 10 may be substantially equally applied to the (2-1)^{th} hole 314 to the extent that they are not contradictory to each other.

Referring to FIGS. 9 and 10, according to an embodiment of the disclosure, first guide elements 511 and 521 may be spaced apart from the second holes 314 and 315 in a first direction (e.g., the first direction D1) when viewed from above the first surface 311 of the first printed circuit board 310. The second guide elements 512 and 522 may be spaced apart from the second holes 314 and 315 in a second direction (e.g., the second direction D2) intersecting the first direction. For example, the first direction and the second direction may be substantially orthogonal to each other.

According to an embodiment of the disclosure, when viewed from above the first surface 311 of the first printed circuit board 310, the first hole 313 may at least partially overlap the electronic component E. In addition, when viewed from above the fourth surface 322 of the second printed circuit board 320, the first hole 313 may at least partially overlap the electronic component E. By disposing the first hole 313 to overlap the electronic component E, the first portion 610 (see FIG. 5) of the heat dissipation material 600 injected through the first hole 313 may stably overlap the electronic component E, and heat may be effectively dissipated from the electronic component E.

According to an embodiment of the disclosure, the first surface 311 of the first printed circuit board 310 may include a surrounding area 311S surrounding the second holes 314 and 315. For example, the surrounding area 311S may be understood as an area within a predetermined distance (e.g., 4 mm) from the second holes 314 and 315. The surrounding area 311S may be referred to as a surrounding area 311S of the second holes 314 and 315 or a surrounding area 311S of the first surface 311 of the first printed circuit board 310.

According to an embodiment of the disclosure, the surrounding area 311S of the second hole 314 or 315 may include a first area 311B positioned between the first hole 313 and the second hole 314 or 315. The surrounding area 311S of the second hole 314 or 315 may include a second area 311A spaced apart from the first area 311B and surrounding the second hole 314 or 315.

According to an embodiment of the disclosure, the guide elements 511, 512, 521, and 522 may be disposed at the second area 311A spaced apart from the first area 311B between the first hole 313 and the second holes 314 and 315. The guide elements 511, 512, 521, and 522 disposed at the second area 311A may at least partially surround the second holes 314 and 315.

According to an embodiment of the disclosure, the first guide elements 511 and 521 may be spaced apart from the second holes 314 and 315 in a first direction (e.g., the first direction D1). The second guide elements 512 and 522 may be spaced apart from the second holes 314 and 315 in a second direction (e.g., the second direction D2) intersecting the first direction. The first direction and the second direction may intersect a direction SD in which the second holes 314 and 315 are spaced apart from the first hole 313. For example, the first direction and the second direction may be substantially orthogonal to each other. For example, the first direction and the second direction may be inclined with respect to a direction SD in which the second holes 314 and 315 are spaced apart from the first hole 313.

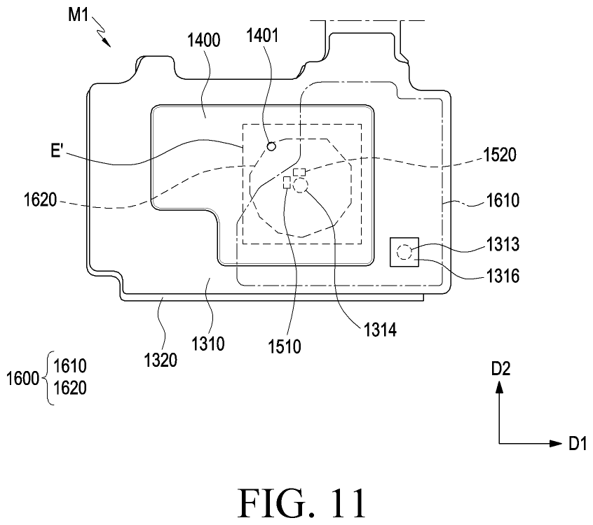

FIG. 11 illustrates a view of the circuit board assembly M1 according to an embodiment of the disclosure as viewed from above the first printed circuit board 1310.

The description of the components of the electronic device according to an embodiment of the disclosure described with reference to FIGS. 5 to 10 (e.g., the circuit board assembly M, the electronic component E, the first printed circuit board 310, the second printed circuit board 320, the first hole 313, the second hole 314, the cap 316, the shield cans 410 and 420, the shield can holes 411 and 421, the guide elements 511, 512, 521, and 522, the heat dissipation material 600, the first portion 610 of the heat dissipation material 600, and/or the second portions 620 and 630 of the heat dissipation material 600) may be substantially equally applied to the components of the electronic device having the same names described with reference to FIG. 11 (e.g., the circuit board assembly M1, the electronic component E′, the first printed circuit board 1310, the second printed circuit board 1320, the first hole 1313, the second hole 1314, the cap 1316, the shield can 1400, the shield can hole 1401, the guide elements 1510 and 1520, the heat dissipation material 1600, the first portion 1610 of the heat dissipation material 1600, and/or the second portion 1620 of the heat dissipation material 1600) to the extent that they are not contradictory to each other.

According to an embodiment of the disclosure, when viewed from above the first printed circuit board 1310, the first hole 1313 may not overlap the electronic component E′. When viewed from above the first printed circuit board 1310, the first hole 1313 may be positioned outside the electronic component E′. The first hole 1313 may be positioned adjacent to an edge of the circuit board assembly M1. For example, the first hole 1313 may be positioned adjacent to an edge of the first printed circuit board 1310.

According to an embodiment of the disclosure, when viewed from above the first printed circuit board 1310, the first hole 1313 may not overlap the shield can 1400. When viewed from above the first printed circuit board 1310, the first hole 1313 may be positioned outside the shield can 1400.

According to an embodiment of the disclosure, when viewed from above the first printed circuit board 1310, the second hole 1314 may overlap the shield can 1400. When viewed from above the first printed circuit board 1310, the second hole 1314 may be positioned inside the shield can 1400. When viewed from above the first printed circuit board 1310, the second hole 1314 may overlap the electronic component E′. When viewed from above the first printed circuit board 1310, the second hole 1314 may be positioned inside the electronic component E′. By disposing the electronic component E′ to overlap the shield can 1400, the second portion 1620 of the heat dissipation material 1600 may stably overlap the electronic component E′, and heat may be effectively dissipated from the electronic component E′ through the second portion 1620 of the heat dissipation material 1600. By disposing the electronic component E′ to overlap the first portion 1610 of the heat dissipation material 1600, heat may be effectively dissipated from the electronic component E′ through the first portion 1610 of the heat dissipation material 1600.

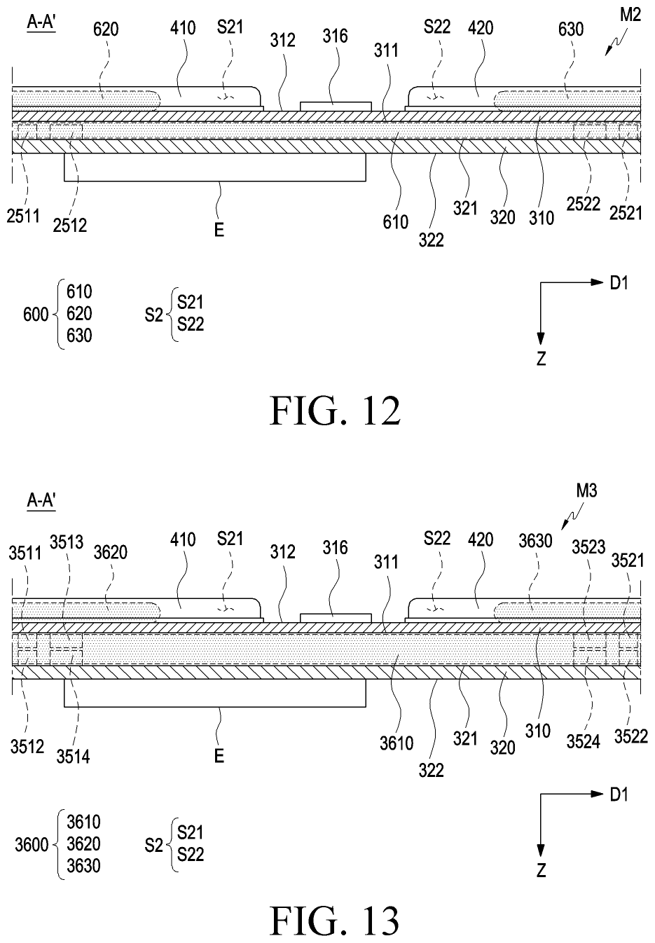

FIG. 12 is a cross-sectional view of a circuit board assembly M2 according to an embodiment of the disclosure, taken along line A-A′ of FIG. 5.

The description of the components of the electronic device according to an embodiment of the disclosure described with reference to FIGS. 5 to 10 (e.g., the circuit board assembly M and/or the guide elements 511, 512, 521, and 522) may be substantially equally applied to the components of the electronic device having the same names described with reference to FIG. 12 (e.g., the circuit board assembly M2 and/or the guide elements 2511, 2512, 2521, and 2522) to the extent that they are not contradictory to each other.

Referring to FIG. 12, according to an embodiment of the disclosure, the guide elements 2511, 2512, 2521, and 2522 may be disposed on the third surface 321 of the second printed circuit board 320. The guide elements 2511, 2512, 2521, and 2522 may be connected to the electronic component E disposed on the fourth surface 322. For example, the guide elements 2511, 2512, 2521, and 2522 may include a decoupling capacitor connected to the electronic component E via the second printed circuit board 320.

FIG. 13 is a cross-sectional view of a circuit board assembly M3 according to an embodiment of the disclosure, taken along line A-A′ of FIG. 5.

The description of the components of the electronic device according to an embodiment of the disclosure described with reference to FIGS. 5 to 10 (e.g., the circuit board assembly M, the heat dissipation material 600, the first portion 610 of the heat dissipation material 600, the second portions 620 and 630 of the heat dissipation material 600, and/or the guide elements 511, 512, 521, and 522) may be substantially equally applied to the components of the electronic device having the same names described with reference to FIG. 13 (e.g., the circuit board assembly M3, the heat dissipation material 3600, the first portion 3610 of the heat dissipation material 3600, the second portions 3620 and 3630 of the heat dissipation material 3600, and/or the guide elements 3511, 3512, 3513, 3514, 3521, 3522, 3523, and 3524) to the extent that they are not contradictory to each other.

Referring to FIG. 13, according to an embodiment of the disclosure, the circuit board assembly M3 may include a plurality of guide elements 3511, 3512, 3513, 3514, 3521, 3522, 3523, and 3524. The plurality of guide elements 3511, 3512, 3513, 3514, 3521, 3522, 3523, and 3524 may be respectively disposed on the first surface 311 of the first printed circuit board 310 and the second surface 321 of the second printed circuit board 320.

According to an embodiment of the disclosure, the plurality of guide elements 3511, 3512, 3513, 3514, 3521, 3522, 3523, and 3524 may include a plurality of first guide elements 3511, 3513, 3521, and 3523 disposed on the first surface 311 of the first printed circuit board 310. The plurality of guide elements 3511, 3512, 3513, 3514, 3521, 3522, 3523, and 3524 may include a plurality of second guide elements 3512, 3514, 3522, and 3524 disposed on the third surface 321 of the second printed circuit board 320. The plurality of first guide elements 3511, 3513, 3521, and 3523 and the plurality of second guide elements 3512, 3514, 3522, and 3524 may overlap each other. The plurality of first guide elements 3511, 3513, 3521, and 3523 and the plurality of second guide elements 3512, 3514, 3522, and 3524 may collectively have a wall shape to guide the flow of the heat dissipation material 3600.

A circuit board assembly including a plurality of components (e.g., a processor and a shield can) may include a plurality of partitioned spaces, and the heat dissipation material may be injected into the plurality of spaces (e.g., the inside of the shield can and a space between the two circuit boards) to enhance heat dissipation performance of the circuit board assembly. Accordingly, extensive studies have been conducted on methods of simplifying a process for filling the heat dissipation material or facilitating the filling of the heat dissipation material in a circuit board assembly including such a plurality of partitioned spaces.

One of the problems addressed by the disclosure may be to reduce the number of injection holes required to inject a gel-type heat dissipation material into internal areas of the circuit board assembly.

Another problem addressed by the disclosure may be to control the flow of the heat dissipation material so that the gel-type heat dissipation material is uniformly distributed into the internal areas of the circuit board assembly.

The issues that the disclosure seeks to address are not limited to the aforementioned issued, and may be expanded in various ways without departing from the spirit and scope of the disclosure.

An electronic device according to various embodiments of the disclosure may reduce the number of injection holes required to inject a gel-type heat dissipation material into separated internal areas of a circuit board assembly by forming a passage that interconnects the internal areas of the circuit board assembly.

An electronic device according to various embodiments of the disclosure may control the flow of the heat dissipation material so that the gel-type heat dissipation material is uniformly distributed into the internal areas of the circuit board assembly by disposing elements configured to guide the flow of the heat dissipation material around the holes through which the gel-type heat dissipation material passes.

The effects obtainable by the disclosure are not limited to the effects mentioned above, and other effects not explicitly mentioned may be clearly understood by those ordinarily skilled in the art to which the disclosure pertains based on the above description.

According to an embodiment of the disclosure, an electronic device 101 may include a housing 210 at least partially forming an exterior of the electronic device 101.

According to an embodiment of the disclosure, the electronic device 101 may include a circuit board assembly M disposed inside the housing 210.

According to an embodiment of the disclosure, the circuit board assembly M may include a first printed circuit board 310 having a first surface 311 and a second surface 312 opposite to the first surface 311.

According to an embodiment of the disclosure, the circuit board assembly M may include a second printed circuit board 320 spaced apart from the first printed circuit board 310 and having a third surface 321 facing the first surface 311.

According to an embodiment of the disclosure, the circuit board assembly M may include an interposer 330 disposed between the first surface 311 and the third surface 321 and configured to electrically connect the first printed circuit board 310 and the second printed circuit board 320.

According to an embodiment of the disclosure, the circuit board assembly M may include a first hole 313 disposed in the first printed circuit board 310 or the second printed circuit board 320 and configured to connect the outside of the circuit board assembly M and a first space S1 defined by the first printed circuit board 310, the second printed circuit board 320, and the interposer 330.

According to an embodiment of the disclosure, the circuit board assembly M may include a shield can 410 or 420 disposed on the second surface 312 of the first printed circuit board 310.

According to an embodiment of the disclosure, the circuit board assembly M may include a second hole 314 or 315 disposed in the first printed circuit board 310 and configured to connect the first space S1 and a second space S2 defined by the shield can 410 or 420 and the first printed circuit board 310.

According to an embodiment of the disclosure, the circuit board assembly M may include a gel-type heat dissipation material 600 disposed in the first space S1 and the second space S2.

According to an embodiment of the disclosure, the circuit board assembly M may include at least one guide element 511, 512, 521, or 522 disposed on at least one of the first surface 311 of the first printed circuit board 310 and the third surface 321 of the second printed circuit board 320.

According to an embodiment of the disclosure, at least one guide element 511, 512, 521, or 522 may at least partially surround the second hole 314 or 315 at a position 311A spaced apart from an area 311B between the first hole 313 and the second hole 314 or 315.

According to an embodiment of the disclosure, at least one guide element 511, 512, 521, or 522 may be configured to guide the heat dissipation material 600, injected into the first space S1 through the first hole 313, to the second hole 314 or 315 so as to allow the heat dissipation material 600 to flow into the second space S2.

According to an embodiment of the disclosure, when viewed from above the first surface 311 of the first printed circuit board 310, the second hole 314 or 315 may be positioned between the first hole 313 and the at least one guide element 511, 512, 521, or 522.

According to an embodiment of the disclosure, when viewed from above the first surface 311 of the first printed circuit board 310, the guide element 511, 512, 521, or 522 may include a first guide element 511 or 521 spaced apart from the second hole 314 or 315 in a first direction.

According to an embodiment of the disclosure, the guide element 511, 512, 521, or 522 may include a second guide element 512 or 522 spaced apart from the second hole 314 or 315 in a second direction intersecting the first direction.

According to an embodiment of the disclosure, the surrounding area 311S of the second hole 314 or 315 may include a first area 311B positioned between the first hole 313 and the second hole 314 or 315.

According to an embodiment of the disclosure, the surrounding area 311S of the second hole 314 or 315 may include a second area 311A spaced apart from the first area 311B and surrounding the second hole 314 or 315.

According to an embodiment of the disclosure, a guide element 511, 512, 521, or 522 may be disposed at the second area 311A of the surrounding area 311S of the second hole 314 or 315.

According to an embodiment of the disclosure, the circuit board assembly M may include an electronic component E disposed on a fourth surface 322 opposite to a third surface 321 of the second printed circuit board 320.

According to an embodiment of the disclosure, when viewed from above the fourth surface 322 of the second printed circuit board 320, the electronic component E may at least partially overlap the shield can 410 or 420.

According to an embodiment of the disclosure, when viewed from above the fourth surface 322 of the second printed circuit board 320, the first hole 313 may at least partially overlap the electronic component E.

According to an embodiment of the disclosure, when viewed from above the first printed circuit board 1310, the second hole 1314 may overlap the electronic component E′.

According to an embodiment of the disclosure, the guide element 2511, 2512, 2521, or 2522 may be disposed on the third surface 321 of the second printed circuit board 320 and may include a decoupling capacitor connected to the electronic component E.

According to an embodiment of the disclosure, the electronic device may include a first thermal diffusion sheet V1 spaced apart from the circuit board assembly M in a direction in which the second surface 312 of the first printed circuit board 310 is oriented and configured to diffuse heat generated from the circuit board assembly M.

According to an embodiment of the disclosure, the electronic device may include a second thermal diffusion sheet V2 spaced apart from the circuit board assembly M in a direction in which the fourth surface 322 of the second printed circuit board 320 is oriented and configured to diffuse heat generated from the circuit board assembly M.

According to an embodiment of the disclosure, the heat dissipation material 600 may include a first portion 610 disposed in the first space S1 and a second portion 620 or 630 disposed in the second space S2.

According to an embodiment of the disclosure, the electronic component E may be positioned between the second thermal diffusion sheet V2 and the first portion 610 of the heat dissipation material 600.

According to an embodiment of the disclosure, the second portion 620 or 630 of the heat dissipation material 600 may be positioned between the first thermal diffusion sheet V1 and the first portion 610 of the heat dissipation material 600.

According to an embodiment of the disclosure, when viewed from above the second surface 312 of the first printed circuit board 310, the second hole 314 or 315 may be covered by the shield can 410 or 420.

According to an embodiment of the disclosure, a height by which the guide element 511, 512, 521, or 522 protrudes from at least one of the first surface 311 of the first printed circuit board 310 and the third surface 321 of the second printed circuit board 320 may be greater than half of a distance between the first surface 311 of the first printed circuit board 310 and the third surface 321 of the second printed circuit board 320.

According to an embodiment of the disclosure, the circuit board assembly M may further include a third hole 317 or 318 disposed in the first printed circuit board 310 and spaced apart from the first hole 313 in a direction intersecting a direction in which the second hole 314 or 315 is spaced apart from the first hole 313.

According to an embodiment of the disclosure, a portion 610 of the heat dissipation material 600 disposed in the first space S1 may be configured to be visually exposed to the outside of the circuit board assembly M through the third hole 317 or 318.

According to an embodiment of the disclosure, the third hole 317 or 318 may be spaced farther from the first hole 313 than the second hole 314 or 315.

Although specific embodiments have been described above in the detailed description of the disclosure, it will be apparent to those skilled in the art that various modifications and changes may be made thereto without departing from the scope of the disclosure.

What is claimed is:

1. An electronic device comprising:
a housing forming an exterior of the electronic device;
a circuit board assembly disposed inside the housing,
wherein the circuit board assembly comprises:
a first printed circuit board comprising a first surface and a second surface opposite to the first surface;
a second printed circuit board comprising a third surface facing the first surface;
an interposer disposed between the first printed circuit board and the second printed circuit board to define a first space with the first printed circuit board and the second printed circuit board, wherein the interposer is configured to electrically connect the first printed circuit board and the second printed circuit board;
a shield can disposed at the second surface of the first printed circuit board to define a second space with the first printed circuit board;
an introducing hole formed in the first printed circuit board;
a heat dissipation material disposed in the first space and the second space; and
at least one guide element disposed on the first surface and/or the third surface and around the introducing hole, wherein the at least one guide element is configured to guide a portion of the heat dissipation material in a gel state injected into the first space to flow into the second space through the introducing hole.

2. The electronic device of claim 1, further comprising:
an injection hole formed in the first printed circuit board and/or the second printed circuit board and configured to connect an outside of the printed circuit board assembly and the first space,
wherein, when viewed from above the first surface of the first printed circuit board, the introducing hole is positioned between the injection hole and the at least one guide element.

3. The electronic device of claim 2, wherein the at least one guide element is formed at at least one of the first surface of the first printed circuit board and the third surface of the second printed circuit board and disposed to at least partially surround the introducing hole at a position spaced apart from an area between the injection hole and the introducing hole.

4. The electronic device of claim 2, wherein the guide element comprises, when viewed from above the first surface of the first printed circuit board, a first guide element spaced apart from the introducing hole in a first direction, and a second guide element spaced apart from the introducing hole in a second direction intersecting with the first direction.

5. The electronic device of claim 2, wherein a surrounding area around the introducing hole comprises:
a first area positioned between the injection hole and the introducing hole; and
a second area spaced apart from the first area and surrounding the introducing hole, wherein the guide element is disposed at the second area.

6. The electronic device of claim 1, wherein the circuit board assembly further comprises:
an electronic component disposed on a fourth surface opposite to the third surface of the second printed circuit board and at least partially overlapping the shield can when viewed from above the fourth surface of the second printed circuit board.

7. The electronic device of claim 6, wherein the introducing hole overlaps the electronic component when viewed from above the first printed circuit board.

8. The electronic device of claim 6, wherein the guide element comprises a decoupling capacitor disposed on the third surface of the second printed circuit board and connected with the electronic component.

9. The electronic device of claim 6, further comprising:
a first thermal diffusion sheet spaced apart from the circuit board assembly in a direction where the second surface of the first printed circuit board is oriented and configured to diffuse a heat generated from the circuit board assembly; and
a second thermal diffusion sheet spaced apart from the circuit board assembly in a direction where the fourth surface of the second printed circuit board is oriented and configured to diffuse the heat generated from the circuit board assembly.

10. The electronic device of claim 9, wherein the heat dissipation material comprises a first portion disposed at the first space and a second portion disposed at the second space,
wherein the electronic component is disposed between the second thermal diffusion sheet and the first portion of the heat dissipation material, and
wherein the second portion of the heat dissipation material is disposed between the first thermal diffusion sheet and the first portion of the heat dissipation material.

11. The electronic device of claim 1, wherein the introducing hole is covered by the shield can when viewed from above the second surface of the first printed circuit board.

12. The electronic device of claim 1, wherein a height of the guide element protruding from at least one of the first surface of the first printed circuit board or the third surface of the second printed circuit board is greater than half of a distance between the first surface of the first printed circuit board and the third surface of the second printed circuit board.

13. The electronic device of claim 1, wherein the circuit board assembly comprises an inspection hole formed in the first printed circuit board and spaced apart from the injection hole in a direction intersecting a direction in which the injection hole is spaced apart from the inspection hole, and
wherein a portion of the heat dissipation material disposed at the first space is visible from an outside of the circuit board assembly through the inspection hole.

14. The electronic device of claim 13, wherein the inspection hole is spaced further apart from the injection hole than the introducing hole.

15. The electronic device of claim 1, wherein the heat dissipation material comprises:
a first portion disposed at the first space; and
a second portion disposed at the second space and overlapping the first portion when viewed from above the second surface of the first printed circuit board.

16. An electronic device comprising:
a housing at least partially forming an exterior of the electronic device;
a circuit board assembly disposed inside the housing,
wherein the circuit board assembly comprises:
a first printed circuit board comprising a first surface and a second surface opposite to the first surface;
a second printed circuit board spaced apart from the first printed circuit board and including a third surface facing the first surface;
an interposer disposed between the first surface and the third surface and configured to electrically connect the first printed circuit board and the second printed circuit board;
a first hole disposed in the first printed circuit board and/or the second printed circuit board and configured to connect an outside of the circuit board assembly and a first space defined by the first printed circuit board, the second printed circuit board, and the interposer;
a shield can disposed on the second surface of the first printed circuit board;
a second hole disposed in the first printed circuit board and configured to connect the first space and a second space defined by the shield can and the first printed circuit board; and
a gel-type heat dissipation material configured to flow into the first space through the first hole and into the second space through the second hole.

17. The electronic device of claim 16, wherein the circuit board assembly further comprises
an electronic component disposed on a fourth surface opposite to the third surface of the second printed circuit board and at least partially overlapping the shield can when viewed from above the fourth surface of the second printed circuit board.

18. The electronic device of claim 16, wherein the circuit board assembly comprises: a third hole disposed in the first printed circuit board and spaced apart from the first hole in a direction intersecting a direction in which the second hole is spaced apart from the first hole, and
wherein a portion of the heat dissipation material disposed in the first space is configured to be visible to an outside of the circuit board assembly through the third hole.

19. The electronic device of claim 16, wherein, when viewed from above the second surface of the first printed circuit board, the second hole is covered by the shield can.

20. The electronic device of claim 16, wherein the heat dissipation material comprises:
a first portion disposed in the first space; and
a second portion disposed in the second space and overlapping the first portion when viewed from above the second surface of the first printed circuit board.
